(19) United States
(12) Patent Application Publication
(10) Pub. No.: US 2010/0044679 A1
(43) Pub. Date: Feb. 25, 2010

(54) Method For Producing Carbon Nanotube Transistor And Carbon Nanotube Transistor Thereby

(75) Inventors: Gyoung-Ho Buh, Suwon-si (KR); Jeong-O Lee, Daejun (KR); Hyunju Chang, Daejun (KR); Ki-jeong Kong, Daejun (KR); Hye-Mi So, Daejun (KR); Jae ho Hwang, Daejun (KR)

Correspondence Address: REINHART BOERNER VAN DEUREN P.C., 2215 PERRYGREEN WAY, ROCKFORD, IL, 61107, US

(73) Assignee: KOREA RESEARCH INSTITUTE OF CHEMICAL TECHNOLOGY, Daejun (KR)

(21) Appl. No.: 12/332,629

(22) Filed: Dec. 11, 2008

Related U.S. Application Data
(63) Continuation of application No. PCT/KR2008/001295, filed on Mar. 7, 2008.

(30) Foreign Application Priority Data
Jan. 22, 2008 (KR) 10-2008-0006535

(51) Int. Cl. H01L 29/78; H01L 21/336; H01L 21/66

(52) U.S. Cl. 257/24; 438/197; 438/17; 977/742; 257/E29.255; 257/E21.521; 257/E21.409; 257/E29.168

(57) ABSTRACT

The present invention relates to a method of manufacturing a carbon nanotube transistor in which a carbon nanotube channel is formed between a source electrode and a drain electrode and a gate electrode is formed at one side of the carbon nanotube channel, the method comprising the steps of: (a) forming the carbon nanotube channel on a substrate; (b) electrically connecting the source electrode and the drain electrode to both ends of the carbon nanotube channel, respectively; and (c) applying a stress voltage across the source electrode and the drain electrode to remove metallicity of the carbon nanotube channel.

According to the method of manufacturing a carbon nanotube transistor of the present invention, a metallic part can be selectively removed from a carbon nanotube which is used as a channel of a transistor and has metallic properties and semiconductor properties mixed with each other.

### CROSS-REFERENCE TO RELATED PATENT APPLICATIONS

This patent application is a Continuation of co-pending PCT Application No. PCT/KR2008/001295, filed Mar. 7, 2008, which claims the benefit of Korean Patent Application No. 10-2008-0006535, filed Jan. 22, 2008, the entire teachings and disclosure of which are incorporated herein by reference thereto.

### DESCRIPTION

1. Technical Field

The present invention relates to a method of manufacturing a carbon nanotube transistor and a carbon nanotube transistor manufactured by the same.

2. Background Art

Carbon nanotubes are expected as a material having industrial applications in a variety of areas including electronic information communication, environment and energy fields because of their excellent electrical, mechanical and chemical characteristics.

Carbon nanotubes are visualized as a graphite sheet rolled having a nanosize-diameter and the conductivity of the carbon nanotubes varies according to the rolling angle and structure of the graphite sheet such that the carbon nanotube has metallic or semiconductor properties.

Furthermore, the carbon nanotubes can be classified into single-walled carbon nanotube (SWNT), double-walled carbon nanotube (DWNT), multi-walled carbon nanotube (MWNT) and rope carbon nanotube according to a degree of lamination of the graphite sheet.

Each of carbon atoms constituting the carbon nanotube is combined with three neighboring carbon atoms according to sp combination method to form a hexagonal honeycomb structure. The carbon nanotube could have metal or semiconductor properties by its diameter and chirality. It is generally known that a third has metal properties and two-thirds has semiconductor properties of which a band gap is inversely proportional to the diameter of the carbon nanotube in SWNT.

The carbon nanotube having the semiconductor properties can be applied to transistors, memory devices and gas sensors and the metallic properties are required for the carbon nanotube to be used as an electrode material.

The carbon nanotube having the semiconductor properties is not required to be additionally doped because it has been doped with impurities. Furthermore, the carbon nanotube can be advantageously used to manufacture a semiconductor chip with high integration because it has a very narrow line width.

However, the metallic properties included with the semiconductor properties in the carbon nanotube must be eliminated in order to use the carbon nanotube as a semiconductor material.

To this end, U.S. Patent Laid-Open Publication No. 2006-223068 discloses a technique of selectively separating a carbon nanotube of semiconductor property from a carbon nanotube of metallic property in fabricated carbon nanotubes in a solution. However, although this technique is suitable for a large quantity of carbon nanotube powder specimen, it is required to spread the separated carbon nanotube on a substrate for making semiconductor device.

Accordingly, there is a need for a method of controlling the property of carbon nanotube to remove only the metallicity of the carbon nanotube in semiconductor device structure, such as a transistor.

3. Disclosure

### Technical Problem

Accordingly, the present invention has been made to solve the above-mentioned problems occurring in the conventional art, and a primary object of the present invention is to provide a method of manufacturing a carbon nanotube transistor for removing metallicity from carbon nanotubes applied to a channel in a device such that the channel has semiconductor properties.

Another object of the present invention is to provide a carbon nanotube transistor manufactured by removing metallicity of carbon nanotube in a channel of a device.

### Technical Solution

According to an aspect of the present invention, there is provided a method of manufacturing a carbon nanotube transistor, in which a carbon nanotube channel is formed between a source electrode and a drain electrode, and a gate electrode is formed at one side of the carbon nanotube channel, the method comprising the steps of: (a) forming the carbon nanotube channel on a substrate; (b) electrically connecting the source electrode and the drain electrode to both ends of the carbon nanotube channel, respectively; and (c) applying a stress voltage across the source electrode and the drain electrode to remove metallicity of the carbon nanotube channel.

The step (c) comprises a process of applying a gate voltage to the gate electrode to deplete carriers in a semiconductor part of the carbon nanotube channel, before the stress voltage is applied or at the same time when the stress voltage is applied.

The method of manufacturing a carbon nanotube transistor may further comprise the steps of: (d) measuring the turn-on current and turn-off current of the carbon nanotube transistor and calculating the ratio of the turn-on current to the turn-off current; and (e) comparing the ratio of the turn-on current to the turn-off current with a reference value to evaluate the performance of the carbon nanotube transistor.

The method of manufacturing a carbon nanotube transistor may further comprise the step of: (f) changing the condition of applying the stress voltage when the ratio of the turn-on current to the turn-off current is smaller than the reference value, and then repeatedly performing the step (c).

The method of manufacturing a carbon nanotube transistor may further comprise the steps of: (g) measuring and calculating a drain current variation according to a gate voltage variation for the carbon nanotube transistor; and (h) comparing the drain current variation according to the gate voltage variation with a reference value to evaluate the performance of the carbon nanotube transistor.

The method of manufacturing a carbon nanotube transistor may further comprise the step of: (i) changing the condition of applying the stress voltage when the drain current variation according to the gate voltage variation is smaller than the reference value, and then repeatedly performing the step (c).

The step of changing the condition of applying the stress voltage may include changing a stress voltage applying time or the stress voltage. The number of times of changing the stress voltage applying time may be limited to a predetermined number of times and the stress voltage may be changed when the number of times of changing the stress voltage applying time exceeds the predetermined number of times.

The gate electrode may be a silicon substrate or a liquid gate electrode formed by exposing the carbon nanotube channel to a liquid, and then bringing a metal electrode into contact with the liquid or inserting the metal electrode into the liquid, the liquid is a liquid with a low ion concentration such as deionized water. The absolute value of the gate voltage is smaller than 1V.

According to another aspect of the present invention, there is provided a carbon nanotube transistor comprising: a source electrode; a drain electrode; and a carbon nanotube channel for interconnecting the source electrode and the drain electrode, wherein carbon nanotubes corresponding to a metallic part mixed with a semiconductor part are thermally cut and lose its metallicity when the carbon nanotube channel is formed.

### Advantageous Effects

As described above, according to the method of manufacturing a carbon nanotube transistor of the present invention, a metallic part can be selectively removed from a carbon nanotube that is used as a channel in a transistor and has both metallic properties and semiconductor properties. Accordingly, the carbon nanotube channel operates in the same manner as a channel formed of only a semiconductor carbon nanotube.

Therefore, according to the method of manufacturing a carbon nanotube of the present invention, the metallicity can be removed from the carbon nanotube channel of the carbon nanotube transistor to strengthen the semiconductor properties so as to remarkably improve the performance of the carbon nanotube transistor.

Accordingly, transistor performances are improved in application fields such as sensors to which the carbon nanotube transistor is applied, and thus the improvement of property of sensors, such as sensitivity, can be expected.

Furthermore, the method of manufacturing a carbon nanotube transistor of the present invention does not select a semiconductor carbon nanotube and use the selected semiconductor carbon nanotube, manufactures a transistor using carbon nanotubes without using a selecting process, and then removes only metallicity from the carbon nanotubes. Accordingly, a manufacturing process is simple, and thus carbon nanotube transistors having high performance can be manufactured in a great quantity with high yield for a short manufacturing time.

### DESCRIPTION OF DRAWINGS

Further objects and advantages of the invention can be more fully understood from the following detailed description taken in conjunction with the accompanying drawings, in which:

FIG. 1 illustrates the concept of a carbon nanotube semiconductor device;

FIG. 2 is a flow chart of a process of removing metallicity from a carbon nanotube channel of carbon nanotube transistors in a method of manufacturing the carbon nanotube transistor according to the present invention;

FIG. 3 illustrates an operation of performing the process of removing metallicity from the carbon nanotube channel illustrated in FIG. 2;

FIG. 4 is a graph showing a turn-on current, a turn-off current and the ratio of the turn-on current to the turn-off current of a carbon nanotube channel of carbon nanotube transistors according to a stress condition applied to the carbon nanotube transistor; and

FIG. 5 is a graph showing a variation in the drain current with respect to the gate voltage of a carbon nanotube transistor after a stress condition is applied to the carbon nanotube transistor.

### BEST MODE

A method of manufacturing a carbon nanotube transistor according to the present invention includes a step of growing carbon nanotubes as a channel between a source electrode and a drain electrode of a transistor, and a step of applying overcurrent to a metallic part of the grown carbon nanotube channel having the metallic part and a semiconductor part, which are mixed with each other, to remove metallicity of the metallic part of the carbon nanotube channel to make the carbon nanotube channel have semiconductor properties, when the transistor is fabricated using the carbon nanotubes.

Here, the overcurrent applied to the metallic part of the carbon nanotube channel changes or destroys the structure of metallic carbon nanotubes to remove the metallicity of the carbon nanotube channel.

It is desirable to apply a predetermined voltage to the gate electrode of the transistor in the step of removing the metallicity of the carbon nanotube channel. When the predetermined voltage is applied to the gate electrode, carriers are depleted in the semiconductor part of the carbon nanotube channel by the gate voltage, and thus the overcurrent applied to the carbon nanotube channel flows through the metallic part rather than the semiconductor part to remove the metallicity in the metallic part of the carbon nanotube channel.

That is, the gate voltage is applied to the transistor to deplete carriers in the semiconductor part of the carbon nanotube channel and change the semiconductor part into a depletion layer so as to increase the electrical resistance of the semiconductor part. Then, a high voltage is applied across the source electrode and the drain electrode such that overcurrent flows through the metallic part of the carbon nanotube channel to efficiently destroy and remove the metallicity of the metallic part. More specifically, the overcurrent applied to carbon nanotubes of the metallic part thermally cuts the structure of the carbon nanotubes to destroy and remove conductivity of the carbon nanotubes, that is, metallicity.

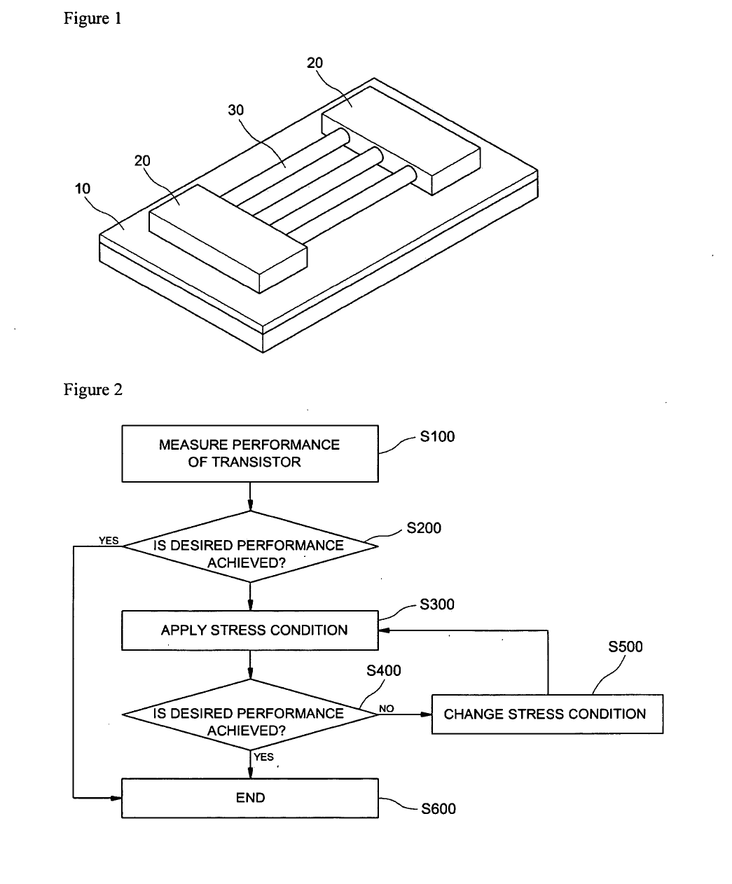

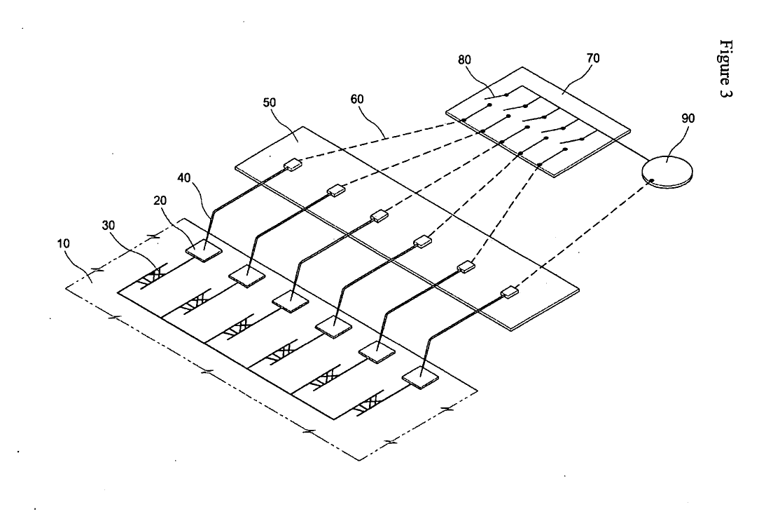

The method of manufacturing a carbon nanotube transistor of the present invention is described in detail with reference to FIGS. 1 and 2.

FIG. 1 illustrates a carbon nanotube transistor manufactured according to the method of manufacturing a carbon nanotube transistor of the present invention.

Referring to FIG. 1, the carbon nanotube transistor of the present invention includes a silicon substrate (Si/SiO2) 10, electrodes 20, and a carbon nanotube channel 30. The electrodes 20 may be a source electrode or a drain electrode and the carbon nanotube channel 30 electrically connects the source and drain electrodes 20 to each other. A method of manufacturing the carbon nanotube transistor illustrated in FIG. 1 is explained below.

First of all, a pattern corresponding to a channel is formed on the silicon substrate 10 insulated with a SiO2 layer formed by oxidizing silicon according to a photolithography method of a semiconductor process. The method of forming the pattern uses a method conventionally used in a photolithography process. In the present embodiment, photoresist is coated on the silicon substrate 10, a mask corresponding to the channel is located above the photoresist layer and light is irradiated to the photoresist layer. A portion of the photoresist layer, which is exposed to the light and denatured, is removed by using an etching solution to form the pattern corresponding to the channel. Here, although the photoresist is not limited to a specific material, it is desirable to use polymethyl methacrylate (PMMA).

Then, a liquid catalyst is introduced in order to form carbon nanotubes in the pattern formed as above. Although Fe/Mo catalyst solution is used as the liquid catalyst in the present embodiment of the present invention, any material capable of promoting the growth of carbon nanotubes can be used as the liquid catalyst. Preferably, transition metals such as Co, Fe, Ni, Mo and Cu, protein including a transition metal, such as Ferritin, reagents containing iron ion, such as FeCl3 and FeSO4, dendrimer containing iron ion or gold nanoparticles can be used as a catalyst for promoting the growth of carbon nanotubes.

Subsequently, the silicon substrate 10 on which carbon nanotubes are reacted with the liquid catalyst is put in acetone solution to completely remove the photoresist layer made of PMMA, and then the catalyst-treated silicon substrate 10 is loaded into a furnace in the ambient of CH4 and H2 at the temperature of 900° and grown for 10 minutes to form single walled carbon nanotubes in the channel.

The electrodes 20 are formed at both ends of the carbon nanotube channel formed as above to fabricate the transistor as illustrated in FIG. 1. The electrodes 20 can be formed using conventional photolithography and thermal evaporation for manufacturing semiconductor devices and detailed explanations thereof are omitted.

It is desirable that the transistor according to the present invention is a MOSFET but it is not limited thereto.

While the carbon nanotube channel of the transistor fabricated as illustrated in FIG. 1 is formed of carbon nanotubes, the carbon nanotube channel includes a metallic part in terms of the property of carbon nanotubes. Accordingly, it is required to remove metallicity in the metallic part of the carbon nanotube channel.

A method of removing the metallicity in the carbon nanotube channel in the method of manufacturing a carbon nanotube transistor according to the present invention is described in detail with reference to FIG. 2.

In the present invention, a process of removing the metallicity in the carbon nanotube channel of the transistor can be performed simultaneously with a wafer probing process for testing whether transistors formed on a wafer are poor through a probe station.

Referring to FIG. 2, first of all, the method of removing the metallicity in the carbon nanotube channel according to the present invention, measures and confirms whether the carbon nanotube channel of a target transistor has metallicity in step S100.

Here, the metallicity of the carbon nanotube channel is confirmed in such a manner that parameters of the transistor, such as the turn-on current, turn-off current and threshold voltage, are measured through a measurement system, and then it is confirmed whether the transistor shows satisfactory performance comparing the measured parameters with a predetermined reference value in step S200.

Specifically, when metallicity of more than a desired level exists in the carbon nanotube channel of the transistor, the transistor cannot accomplish desired performance. Accordingly, it can be confirmed whether metallicity exists in the carbon nanotube channel of the transistor by measuring the ratio of the turn-on current to the turn-off current, threshold voltage or transconductance of the transistor.

The reference value can use a value previously input by a user and stored and can be controlled to various values according to the desired performance of the transistor.

In a case where the performance of the transistor is satisfied when the parameters are compared with the reference value, the process of removing metallicity is not performed in step S600.

However, when the desired performance of the transistor is not satisfied, that is, when a metallic part of more than a predetermined level exists in the carbon nanotube channel of the transistor, a stress voltage is applied across the source electrode 20 and the drain electrode 20 of the transistor to leave the carbon nanotube channel 30 between the source electrode 20 and the drain electrode 20 under a predetermined stress condition in step S300. Under this stress condition, the predetermined stress voltage is applied for a predetermined period of time. The process of removing metallicity is stopped when the stress condition exceeds a predetermined range and the process is applied when the stress condition is in the predetermined range.

When the stress voltage is applied to the carbon nanotube channel between the source electrode and the drain electrode, overcurrent flows through the carbon nanotube channel according to the applied stress voltage and applies stress to the carbon nanotube structure of the metallic part of the carbon nanotube channel. This stress cuts the carbon nanotube structure to change the carbon nanotube structure, and thus carbon nanotubes of the carbon nanotube channel lose metallicity. When carbon nanotubes in the carbon nanotube channel lose metallicity, the resistance of the carbon nanotube channel increases to result in loss of metallicity of the carbon nanotube channel.

Meanwhile, it is desirable that the stress condition is not applied to the semiconductor part existing in the carbon nanotube channel. To achieve this, it is desirable that a voltage is applied to one side of the carbon nanotube channel, that is, the gate electrode of the transistor, which is formed in a position to which electric field can be applied, to change the semiconductor part of the carbon nanotube channel into a depletion layer, that is, to deplete carriers in the semiconductor part, when the stress condition is applied.

The stress condition is applied to remove metallicity of the carbon nanotube channel, and then the performance of the transistor is measured again to confirm whether the desired performance is achieved in step S400.

When the desired performance is not achieved, the stress condition is changed and the changed stress condition is applied to repeat the process of removing metallicity in step S500.

It is desirable to repeatedly apply the stress condition through the following method.

Whenever the same stress voltage is applied, a stress applying time is increased. For example, the stress applying time is increased to 0.01 seconds, 0.05 seconds and 0.25 seconds etc. When the performance of the transistor is not satisfied even after a stress is applied for a predetermined time, it is desirable to limit the number of changing the stress applying time to prevent a process time from excessively increasing.

That is, when the performance of the transistor is not satisfied even after a stress condition corresponding to a predetermined maximum allowable stress applying time (for example, 0.25 seconds) is applied, a method of increasing the stress voltage is used. For example, the stress voltage is increased by 5V.

When it is confirmed that the desired performance of the transistor is achieved according to the measurement of the performance of the transistor after the stress condition is applied in stages, the process of removing metallicity in the carbon nanotube channel of the transistor is finished.

Hereinafter, the method of removing metallicity of a carbon nanotube channel of a corresponding transistor using a semiconductor device measurement system for transistors formed on a substrate is explained with reference to FIG. 3.

Referring to FIG. 3, a plurality of transistors to be tested exist on a substrate 10 and each of the transistors includes a source electrode 20 and a drain electrode 20 connected to each other through a carbon nanotube channel 30.

A process of measuring the performance of the transistor through a probe card 50 which comes into contact with the electrodes 20 and applies a signal and a process of removing metallicity are performed on the transistor. The probe card 50 includes a plurality of probes 40 which come into contact with the electrodes of the plurality of transistors to apply signals.

The probe card 50 is connected to a measurement system 90 through a matrix switching system 70. The probe card 50 is connected to the matrix switching system 70 through signal lines 60.

Here, the matrix switching system 70 controls a plurality of internal switches 80 corresponding to transistors to be tested to apply a stress condition suitable to the transistors.

When the process of measuring the performance of a transistor and a process of removing metallicity from the transistor are finished, the measurement system 90 controls the switches 80 of the matrix switching system 70 to sequentially test following to-be-tested transistors.

Here, when the process of measuring transistor performance and the process of removing metallicity have been sequentially performed on all the transistors included in a single die, the measurement system 90 moves to another die on the substrate and carries out the transistor performance measurement and metallicity removal processes.

It is also desirable to carry out the transistor performance measurement and metallicity removal process to the whole dies of a wafer simultaneously, with the probe card which covers whole dies to reduce the process time.

Meanwhile, the result of the metallicity removal process, for example, data of transistors included in dies or in each die that have passed standards, is stored and can be used as performance data of transistors even after the substrate is cut into respective dies and wire bonding and packaging are performed.

As described above, it is desirable to apply a predetermined voltage to the gate electrode to deplete carriers in the semiconductor part of the carbon nanotube channel in order to increase the resistance of the semiconductor part of the carbon nanotube channel, when the stress voltage is applied across the source electrode and the drain electrode. Here, a silicon substrate can be used as the gate electrode.

In another preferred embodiment, the gate electrode is not additionally formed and a liquid gate, which is formed by exposing the carbon nanotube channel 40 to a liquid and bringing a metal electrode into contact with the liquid or putting the metal electrode into the liquid, can be used. Here, it is desirable to use a liquid with a low ion concentration, such as deionized water, as the liquid in order to prevent ion current from flowing through the liquid or prevent the liquid from electrolysis.

In a case where the liquid gate is used, it is desirable to form a passivation layer using photoresist to expose only the carbon nanotube channel region in order to protect metal conductor patterns of a source and a drain and the electrodes 20.

When the liquid gate is used, it is desirable that the absolute value of the gate voltage is smaller than 1V that can sufficiently deplete carriers in the semiconductor part of the carbon nanotube channel. When the gate voltage is excessively high, the liquid used for the liquid gate may be electrolyzed, and thus the liquid gate is not suitable for the transistor.

As described above, the present invention can test transistors formed on a substrate such as a wafer by the probe card 50 and, simultaneously, remove metallicity in the carbon nanotube channel of each transistor.

While the present invention is described in more detail below through an example, the scope of the present invention is not limited to the example.

### EXAMPLE

SiO2/Si substrate is prepared and PMMA layer is formed thereon and patterned to remove a portion of the PMMA layer, which corresponds to a channel of a transistor. Fe/Mo catalytic solution is coated on the patterned portion corresponding to the channel, and then the PMMA layer is removed through lift-off.

The SiO2/Si substrate having the portion corresponding to a channel, coated with Fe/Mo catalytic solution is loaded into a furnace in the ambient of CH4 and H2 and the furnace is heated to 900° for 10 minutes to grow carbons on the portion corresponding to the channel to form a single walled carbon nanotube channel.

Electrode patterns are formed on portions of the substrate, which correspond to both sides of the carbon nanotube channel, through photolithography method, and then Ti with a thickness of 5 nm and Au with a thickness of 30 nm are sequentially deposited using thermal evaporation while maintaining a vacuum to form electrodes. Subsequently, the substrate is put into acetone solution to remove metals such as Ti and Au deposited on an undesired portion to obtain a carbon nanotube transistor.

Subsequently, the performance of the carbon nanotube transistor obtained as above is measured.

To measure the performance of the transistor, the drain current, turn-on current Ion and turn-off current Ioff are measured and the ratio of the turn-on current Ion to the turn-off current Ioff, that is, Ion/Ioff, is calculated. In the present embodiment, a reference value for Ion/Ioff is set to 20.

The measurement of the performance of the transistor is repeated while changing a stress condition in stages until the measured Ion/Ioff exceeds the reference value.

The stress condition is applied in stages in such a manner that a voltage of 10V is applied across the source and drain electrodes while increasing a voltage applying time to 0.01 seconds, 0.05 seconds and 0.25 seconds. After the voltage is applied for 0.25 seconds, the voltage is increased by 5V, and then the stress condition is repeatedly applied while increasing the voltage applying period to 0.01 seconds, 0.05 seconds and 0.25 seconds.

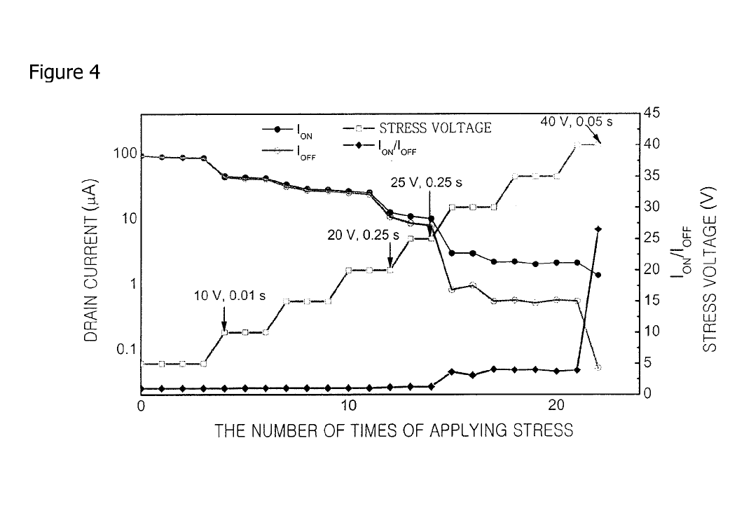

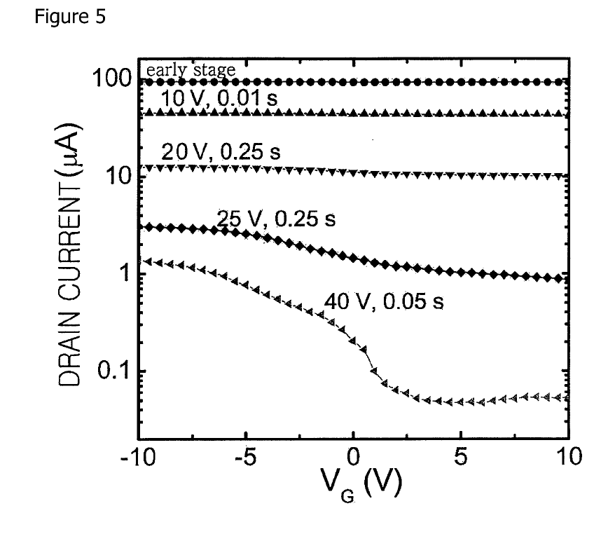

Measurement values according to the aforementioned stress condition are illustrated in FIGS. 4 and 5.

It can be known from FIG. 4 that a drain current value is reduced when a stress voltage 10V is applied for 0.01 seconds, when 20V is applied for 0.25 seconds and when 25V is applied for 0.25 seconds. From this result, it can be known that metallicity of the carbon nanotube channel is reduced but the reduction in the metallicity is not so large as the performance of the transistor is satisfied.

However, when 40V is applied for 0.05 seconds, the turn-off current Ioff is abruptly decreased as compared to the turn-on current Ion, and thus Ion/Ioff is suddenly increased and exceeds the reference value. From this result, it can be confirmed that the carbon nanotube transistor shows satisfactory transistor performance.

It can be confirmed from FIG. 4 that the metallic part of the carbon nanotube channel is removed so that the carbon nanotube channel has semiconductor properties when a stress condition suitable for the carbon nanotube channel of the carbon nanotube transistor is applied.

Meanwhile, FIG. 5 shows a drain current ID measured as a function of a gate voltage VG whenever the metallic part is removed from the carbon nanotube channel after a stress condition is applied. It can be confirmed from FIG. 5 that a device, which does not show transistor performance because the drain current is not varied, even though the gate voltage is changed when the stress condition is not applied or when an appropriate stress condition is not applied, shows excellent transistor performance in that the drain current ID is varied according to a gate voltage variation, after 40V is applied for 0.05 second as stress condition.

Furthermore, it can be confirmed from FIG. 5 that the confirmation of the transistor performance can also be made by measuring a variation in the drain current ID according to a variation in the gate voltage VG in the present invention.

Results obtained by applying the method of the present invention to dies including 12 transistors respectively are arranged in Table 1.

TABLE 1

| | | | | | | Success rate |
|---|---|---|---|---|---|---|
| | | | Before removal of | | | Dies |
| | | | metallicity | | After | including at |
| | | | The | | removal of | least three |
| | | | number | | metallicity | high-performance |
| | The | | of carbon | Iₒₙ/I_{off} is | Iₒₙ/I_{off} is | carbon |
| | number | The number | nanotube | greater | greater than | nanotube |
| Experiment | of dies | of transistors | channels | than 20 | 20 | transistors |
| 1 | 2 | 24 | 14 | 0 | 14 | 100 |
| 2 | 9 | 108 | 69 | 6 | 60 | 100 |
| 3 | 11 | 132 | 65 | 6 | 34 | 100 |

It can be confirmed from Table 1 that a plurality of transistors having unsatisfied performances achieve desired transistor performances because Ion/Ioff is remarkably increased after the process of removing metallicity in the method of manufacturing a carbon nanotube transistor of the present invention is performed. In particular, it can be known that 100% yield is obtained when a case where at least three carbon nanotube field effect transistors (CNTFETs) corresponding to high-performance carbon nanotube transistors are integrated into a single die is determined as final yield.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of manufacturing a carbon nanotube transistor in which a carbon nanotube channel is formed between a source electrode and a drain electrode and a gate electrode is formed at one side of the carbon nanotube channel, the method comprising the steps of:
(a) forming the carbon nanotube channel on a substrate;
(b) electrically connecting the source electrode and the drain electrode to both ends of the carbon nanotube channel, respectively; and
(c) applying a stress voltage across the source electrode and the drain electrode to remove metallicity in the carbon nanotube channel.

2. The method according to claim 1, wherein a gate voltage is applied to the gate electrode to deplete carriers in a semiconductor part of the carbon nanotube channel, before the stress voltage is applied or at the same time when the stress voltage is applied in the step (c).

3. The method according to claim 1, further comprising the steps of:
(d) measuring a turn-on current and a turn-off current of the carbon nanotube transistor and calculating the ratio of the turn-on current to the turn-off current; and
(e) comparing the ratio of the turn-on current to the turn-off current with a reference value to evaluate a performance of the carbon nanotube transistor.

4. The method according to claim 3, further comprising the step of:
(f) changing the condition of applying the stress voltage when the ratio of the turn-on current to the turn-off current is smaller than the reference value, and then performing the step (c) again,
wherein the step of changing the condition of applying the stress voltage comprises varying a stress voltage applying time or the stress voltage.

5. The method according to claim 4, wherein the number of times of changing the stress voltage applying time is limited to a predetermined number of times, and the stress voltage is changed when the number of times of changing the stress voltage applying time exceeds the predetermined number of times.

6. The method according to claim 1, further comprising the steps of:
(g) measuring and calculating a drain current variation according to a gate voltage variation for the carbon nanotube transistor; and
(h) comparing the drain current variation according to the gate voltage variation with a reference value to evaluate performance of the carbon nanotube transistor.

7. The method according to claim 6, further comprising the step of:
(i) changing the condition of applying the stress voltage when the drain current variation according to the gate voltage variation is smaller than the reference value, and then performing the step (c) again,
wherein the step of changing the condition of applying the stress voltage comprises varying a stress voltage applying time or the stress voltage.

8. The method according to claim 7, wherein the number of times of changing the stress voltage applying time is limited to a predetermined number of times, and the stress voltage is changed when the number of times of changing the stress voltage applying time exceeds the predetermined number of times.

9. The method according to claim 1, wherein the gate electrode is a silicon substrate.

10. The method according to claim 1, wherein after the carbon nanotube channel has been exposed to a liquid, a metal electrode is brought into contact with the liquid or inserted into the liquid to form a liquid gate electrode and use the liquid gate electrode.

11. The method according to claim 10, wherein the liquid is a liquid with a low ion concentration, such as deionized water.

12. The method according to claim 11, wherein the absolute value of the gate voltage is smaller than 1V.

13. A carbon nanotube transistor comprising:
a source electrode;
a drain electrode; and
a carbon nanotube channel for interconnecting the source electrode and the drain electrode,
wherein carbon nanotubes of a metallic part mixed with a semiconductor part are thermally cut and lose metallicity when the carbon nanotube channel is formed.
